(19) United States
(12) Patent Application Publication
(10) Pub. No.: US 2024/0395712 A1
(43) Pub. Date: Nov. 28, 2024

(54) SEMICONDUCTOR DEVICE AND METHOD FOR FABRICATING THE SAME

(71) Applicant: Samsung Electronics Co., Ltd., Suwon-si (KR)

(72) Inventors: Dong Hoon Kwon, Suwon-si (KR); Il Young Yoon, Suwon-si (KR)

(21) Appl. No.: 18/530,763

(22) Filed: Dec. 6, 2023

(30) Foreign Application Priority Data
May 24, 2023 (KR) 10-2023-0066959

(51) Int. Cl. H01L 23/528; H01L 21/8238; H01L 23/48; H01L 27/092

(52) U.S. Cl. CPC H01L 23/5286; H01L 21/823821; H01L 21/823871; H01L 23/481; H01L 27/0924

(57) ABSTRACT

A semiconductor device and a method of fabricating the same are provided. The semiconductor device includes a substrate including a frontside on which an active pattern is formed and a backside opposite the frontside, an electronic element on an active region in which the active pattern is formed, a frontside interconnection structure, in which a power line connected to the electronic element is disposed, on the frontside of the substrate, a backside interconnection structure, which includes a backside line connected to the electronic element, on the backside of the substrate, a through via connecting the power line with the backside line by passing through the substrate, and a dummy mold structure on the frontside interconnection structure, having a first cross-sectional thickness greater than a second cross-sectional thickness of the frontside interconnection structure.

### CROSS-REFERENCE TO RELATED APPLICATION

This application claims priority under 35 U.S.C. § 119 to Korean Patent Application No. 10-2023-0066959 filed on May 24, 2023 in the Korean Intellectual Property Office, the contents of which in its entirety are herein incorporated by reference.

### BACKGROUND

The present disclosure relates generally to a semiconductor device and a method for fabricating the same, and more particularly to a semiconductor device including a backside line pattern and a method for fabricating the same.

Semiconductor devices in the electronic industry have been spotlighted as an important factor due to characteristics of miniaturization, multi-functionalization and/or low fabricating costs. The semiconductor devices may be classified into a semiconductor memory device for storing logic data, a semiconductor logic device for processing logic data, and a hybrid semiconductor device including a memory element and a logic element.

With the highly advanced electronic industry, there is an increasing demand for improved characteristics of the semiconductor device. For example, there is an increasing demand for high reliability, high speed, and/or multi-functionalization for the semiconductor device. In order to fulfil these requirements, structures in the semiconductor device have been increasingly complicated and highly integrated.

### BRIEF SUMMARY

Some embodiments of the present disclosure provide a semiconductor device having improved reliability and performance.

Further embodiments of the present disclosure provide a method for fabricating a semiconductor device having improved reliability and performance.

Embodiments of the present disclosure are not limited to those mentioned above and additional embodiments of the present disclosure, which are not mentioned herein, will be clearly understood by those skilled in the art from the following description of the present disclosure.

A semiconductor device according to some embodiments comprises a substrate including a frontside on which an active pattern is formed and a backside facing the frontside, an electronic element disposed on an active region in which the active pattern is formed, a frontside interconnection structure, in which a power line connected to the electronic element is disposed, on the frontside of the substrate, a backside interconnection structure, which includes a backside line connected to the electronic element, on the backside of the substrate, a through via connecting the power line with the backside line by passing through the substrate, and a dummy mold structure disposed on the frontside interconnection structure, having a thickness greater than that of the frontside interconnection structure.

A method for fabricating a semiconductor device according to some embodiments comprises providing a semiconductor substrate including a first surface on which an active region is formed and a second surface facing the first surface, forming an electronic element on the active region, forming a frontside interconnection structure, which is connected to source/drain regions of the electronic element, on the first surface of the semiconductor substrate, forming a first dummy mold structure, in which a first bonding layer is formed, on the frontside interconnection structure, providing a carrier substrate including a third surface and a fourth surface, which face each other, forming a second dummy mold structure, in which a second bonding layer is formed, on the third surface of the carrier substrate, bonding the semiconductor substrate to the carrier substrate by disposing the first bonding layer and the second bonding layer to face each other, and forming a backside interconnection structure, which is connected to the source/drain regions, on the second surface of the semiconductor substrate.

A method for fabricating a semiconductor device according to some other embodiments comprises providing a semiconductor substrate including an active region defined by an element isolation trench and including a first surface and a second surface, which face each other, forming an electronic element including an active pattern disposed on the active region and extended in one direction, a gate structure extended in a direction crossing the one direction and source/drain regions disposed on sides of the gate structure, forming a frontside interconnection structure, in which a power line connected to the source/drain regions is disposed, on the first surface of the semiconductor substrate, forming a first dummy mold structure, in which a first bonding layer is formed, on the frontside interconnection structure, forming a carrier substrate including a third surface and a fourth surface, which face each other, and forming a second dummy mold structure, in which a second bonding layer is formed, on the third surface of the carrier substrate, wherein the first dummy mold structure is disposed between the frontside interconnection structure and the first bonding layer, and the second dummy mold structure is disposed between the third surface of the carrier substrate and the second bonding layer.

Details of other embodiments are included in the detailed description and drawings.

### BRIEF DESCRIPTION OF THE DRAWINGS

The above and other aspects and features of the present disclosure will become more apparent by describing in detail exemplary embodiments thereof with reference to the attached drawings, in which the same or similar elements will be denoted by the same reference labels throughout the specification and the drawings, and in which:

FIG. 1 is a schematic layout view (i.e., top plan view) illustrating at least a portion of an example semiconductor device, according to some embodiments;

FIG. 2 is a cross-sectional view of the semiconductor device shown in FIG. 1, taken along line A-A of FIG. 1;

FIG. 3 is a cross-sectional view of the semiconductor device shown in FIG. 1, taken along line B-B of FIG. 1;

FIG. 4 is a cross-sectional view of the semiconductor device shown in FIG. 1, taken along line C-C of FIG. 1;

FIGS. 5 to 7 are cross-sectional views illustrating at least a portion of an example semiconductor device according to some embodiments, corresponding to FIG. 2;

FIGS. 8 to 18 are cross-sectional views illustrating intermediate steps to describe an example method for fabricating a semiconductor device according to some embodiments; and

FIGS. 19 to 21 are cross-sectional views illustrating intermediate steps to describe an example method for fabricating a semiconductor device according to some embodiments.

### DETAILED DESCRIPTION

It will be understood that, although the ordinal terms “first”, “second”, etc. may be used herein to describe various elements or components, these elements or components should not be limited by these terms. These terms are only used to distinguish one element or component from another element or component. Therefore, a first element or component discussed below could be termed a second element or component without departing from the technical spirits of the present disclosure.

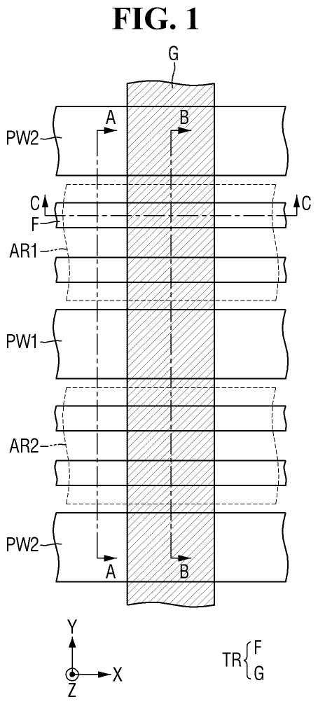

Hereinafter, a semiconductor device according to exemplary embodiments will be described with reference to FIGS. 1 to 4.

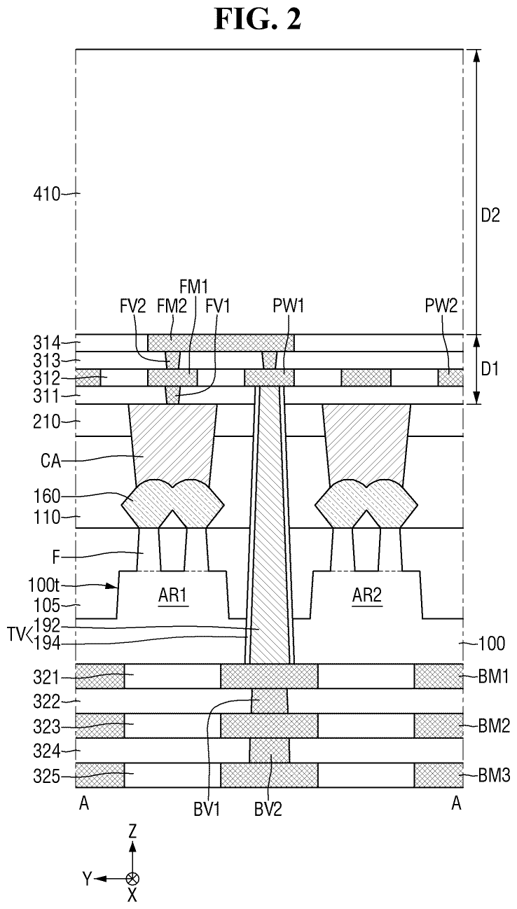

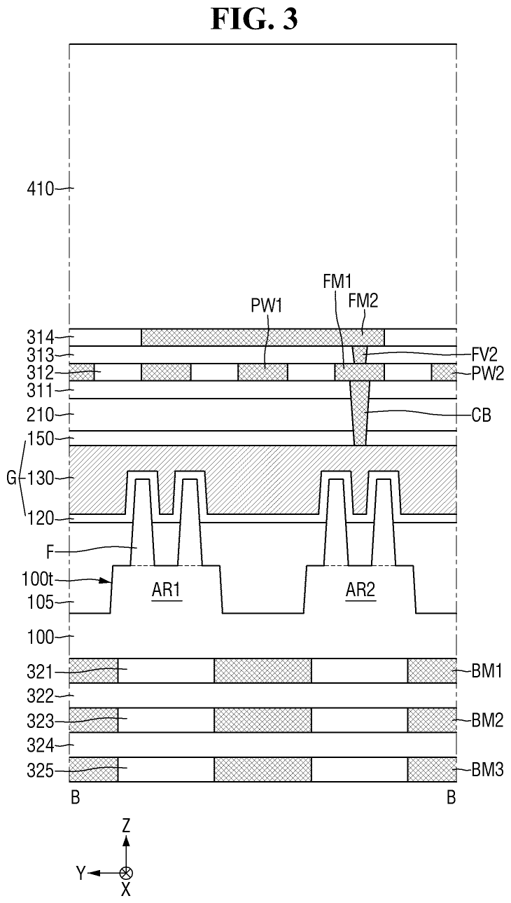

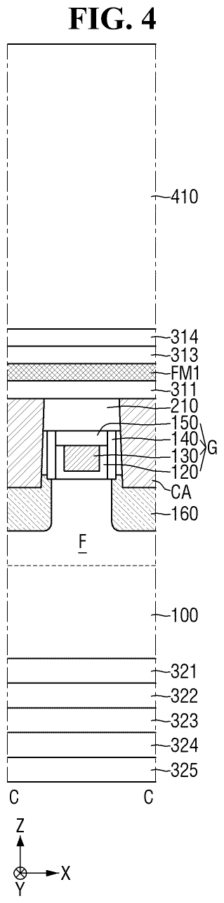

FIG. 1 is a schematic layout view (i.e., top plan view) illustrating at least a portion of an example semiconductor device according to some embodiments. FIG. 2 is a cross-sectional view of the semiconductor device shown in FIG. 1, taken along line A-A of FIG. 1. FIG. 3 is a cross-sectional view of the semiconductor device shown in FIG. 1, taken along line B-B of FIG. 1. FIG. 4 is a cross-sectional view of the semiconductor device shown in FIG. 1, taken along line C-C of FIG. 1.

In FIGS. 1 to 4, a logic device is shown as an example of the semiconductor device, but this is only exemplary. As another example, the semiconductor device may include a system large scale integration (LSI), a flash memory, a dynamic random-access memory (DRAM), a static random-access memory (SRAM), an electrically-crasable programmable read-only memory (EEPROM), a phase-change random-access memory (PRAM), a magnetic random-access memory (MRAM), a resistive random-access memory (RERAM), an image sensor such as a CMOS imaging sensor (CIS), a micro-electro-mechanical system (MEMS), an active device, a passive device, and the like.

Referring to FIGS. 1 to 4, a semiconductor device according to some embodiments includes a substrate 100, an electronic element TR, interlayer insulating layers 110 and 210, frontside interconnection structures 311 to 314, FM1, FM2, FV2 and FV2, power lines PW1 and PW2, backside interconnection structure 321 to 325, BM1 to BM3, BV1 and BV2, and a dummy mold structure 410.

The substrate 100 may be a bulk silicon or a silicon-on-insulator (SOI). Alternatively, the substrate 100 may be a silicon substrate, or may include other material, for example, silicon germanium, silicon germanium on insulator (SGOI), indium antimonide, lead telluride, indium arsenide, indium phosphide, gallium arsenide or gallium antimonide, but is not limited thereto.

The substrate 100 may include first and second active regions AR1 and AR2. The first and second active regions AR1 and AR2 may be defined by an element isolation trench 100t in the substrate 100. The element isolation trench 100t may be a deep trench formed in the substrate 100. For example, the element isolation trench 100t may be extended in a first direction X parallel with an upper surface of the substrate 100 to laterally separate (e.g., in a second direction Y, parallel with the upper surface of the substrate 100 and intersecting the first direction X) the first and second active regions AR1 and AR2 from each other.

In the present disclosure, a surface of the substrate 100 (e.g., the upper surface of the substrate 100) on which the active regions AR1 and AR2 are formed may be referred to as a frontside of the substrate 100. In addition, a surface of the substrate 100 (e.g., a lower surface of the substrate 100) opposite to the front surface of the substrate 100 may be referred to as a backside of the substrate 100.

In some embodiments, electronic elements (e.g., transistors) of different conductivity types (e.g., n-type or p-type) may be alternately arranged on the active regions AR1 and AR2. In the following description, the first active region AR1 is a p-type (or p-channel) field-effect transistor (PFET) region, and the second active region AR2 is an n-type (or n-channel) field-effect transistor (NFET) region. However, this is only exemplary, and the first active region AR1 may be an NFET region and the second active region AR2 may be a PFET region.

The electronic element TR (e.g., transistor) may be formed on the substrate 100. For example, the electronic element TR may be formed on each of the first and second active regions AR1 and AR2. In some embodiments, the electronic element TR may include an active pattern F, a gate structure G and source/drain regions 160.

The active pattern F may be formed on an upper surface of each of the first and second active regions AR1 and AR2. The plurality of active patterns F may be laterally spaced apart from each other (in the second direction Y) and extend in the first direction X. Although only two active patterns F are formed on the respective first and second active regions AR1 and AR2, this is only exemplary and the number of the active patterns F may vary. In some embodiments, the active pattern F may be a fin-type pattern extending from the upper surface of the first and second active regions AR1 and AR2 and extended in the first direction X.

In some embodiments, a field insulating layer 105 may be formed on the substrate 100. The field insulating layer 105 may surround at least a portion of a side of the active patterns F. The term “surround” (or “surrounding,” or like terms) as may be used herein is intended to broadly refer to an element, structure or layer that extends around, envelops, encircles, or encloses another element, structure or layer on all sides, although breaks or gaps may also be present. Thus, for example, a material layer having voids therein may still “surround” another layer which it encircles. For example, as shown in FIG. 3, a portion of each of the active patterns F may extend above an upper surface of the field insulating layer 105 in a third direction Z, relative to the lower surface of the substrate 100. The field insulating layer 105 may fill the element isolation trench 100t. That is, the active regions AR1 and AR2 may be spaced apart from each other by the field insulating layer 105. The term “fill” (or “filling,” “filled,” or like terms) as may be used herein is intended to refer broadly to either completely filling a defined space (e.g., isolation trench 100t) or partially filling the defined space; that is, the defined space need not be entirely filled but may, for example, be partially filled or have voids or other spaces throughout.

The field insulating layer 105 may include at least one of, for example, silicon oxide (SiO₂), silicon oxynitride (SiON), silicon oxycarbonitride (SiOCN) or their combination, but is not limited thereto.

The gate structure G may be formed on the active pattern F. The gate structure G may cross the active pattern F. For example, the gate structure G may extend in the second direction Y crossing (i.e., intersecting) the first direction X in parallel with the upper surface of the substrate 100.

In some embodiments, the gate structure G may include a gate electrode 130, a gate dielectric layer 120, a gate spacer 140 and a gate capping pattern 150.

The gate electrode 130 of the gate structure G may extend in the second direction Y. The gate electrode 130 may include at least one of, for example, titanium (Ti), tantalum (Ta), tungsten (W), aluminum (Al), cobalt (Co), or a combination thereof, but is not limited thereto. The gate electrode 130 may include, for example, silicon or silicon germanium, not a metal.

The gate electrode 130 is shown as a single layer, but the present disclosure is not limited thereto. Unlike the example shown in FIGS. 1-4, the gate electrode 130 may be formed by stacking a plurality of conductive materials. For example, the gate electrode 130 may include a work function adjustment layer for adjusting a work function and a filling conductive layer for filling a space formed by the work function adjustment layer. The work function adjustment layer may include at least one of, for example, titanium nitride (TiN), tantalum nitride (TaN), titanium carbide (TiC), tantalum carbide (TaC), titanium aluminum carbide (TiAlC), or a combination thereof, although the present disclosure is not limited thereto. The filling conductive layer may include, for example, W or Al, although embodiments are not limited thereto. The gate electrode 130 may be formed by, for example, a replacement process, but is not limited thereto.

The gate dielectric layer 120 may be interposed between the active patterns F and the gate electrode 130. For example, the gate dielectric layer 120 may extend along an upper surface and sides of the active patterns F. In some embodiments, the gate dielectric layer 120 may further extend along an upper surface of the field insulating layer 105. In some embodiments, the gate dielectric layer 120 may further extend along sides of the gate spacer 140.

The gate dielectric layer 120 may include at least one of, for example, silicon oxide, silicon oxynitride, silicon nitride or a high dielectric constant (high-k) material having a dielectric constant greater than that of silicon oxide. The high-k material may include, for example, hafnium oxide, but is not limited thereto.

The gate spacer 140 may be formed on the substrate 100 and the field insulating layer 105. The gate spacer 140 may extend along both sides of the gate electrode 130. The gate spacer 140 may include at least one of, for example, silicon oxide, silicon nitride, silicon oxynitride or a combination thereof, but is not limited thereto.

The gate capping pattern 150 may extend along an upper surface of the gate electrode 130. The gate capping pattern 150 may include at least one of, for example, silicon oxide, silicon nitride, silicon oxynitride or a combination thereof, but is not limited thereto.

The source/drain regions 160 may be formed on the active pattern F. For example, the source/drain regions 160 may be formed in the active pattern F on both sides of the gate structure G. The source/drain regions 160 may be laterally spaced apart (in the first direction X) from the gate electrode 130 by the gate spacer 140 of the gate structure G.

In some embodiments, the source/drain regions 160 may include an epitaxial layer formed on the active pattern F. The source/drain region 160 is shown as being only an epitaxial layer merged with respect to the plurality of active patterns F, but this is only exemplary. As another example, at least a portion of the source/drain regions 160 may be an unmerged epitaxial layer.

The source/drain region 160 formed on a PFET region (e.g., the first active region AR1) may include p-type impurities or impurities for preventing diffusion of the p-type impurities. For example, the source/drain regions 160 of the PFET region may include at least one of boron (B), carbon (C), indium (In), gallium (Ga), Al or a combination thereof, but are not limited thereto.

The source/drain regions 160 formed on an NFET region (e.g., the second active region AR2) may include n-type impurities or impurities for preventing diffusion of the n-type impurities. For example, the source/drain regions 160 of the NFET region may include at least one of phosphorous (P), antimony (Sb), arsenic (As), or a combination thereof, but are not limited thereto.

Each of the source/drain regions 160 is shown as only a single layer, but embodiments of the present disclosure are not limited thereto. For example, the source/drain regions 160 may be formed of multiple epitaxial layers that include impurities of different concentrations.

A fin-type transistor FinFET including a channel region of a fin-type pattern is described as an example of the electronic element TR, but this is only exemplary. As another example, the electronic element TR may include a tunneling transistor (tunneling FET), a transistor including a nanowire, a transistor including a nanosheet, a Vertical FET (VFET), a Complementary FET (CFET) or a three-dimensional (3D) transistor. Alternatively, the electronic element TR may include a bipolar junction transistor, a laterally-diffused metal-oxide-semiconductor (LDMOS) transistor, and the like.

In some embodiments, the electronic element TR may include a negative capacitance (NC) FET based on a negative capacitor. For example, the gate dielectric layer 120 may include a ferroelectric material layer having ferroelectric characteristics and a paraelectric material layer having paraelectric characteristics.

The ferroelectric material layer may have a negative capacitance, and the paraelectric material layer may have a positive capacitance. For example, when two or more capacitors are connected in series and the capacitance of each capacitor has a positive value, the total capacitance is more reduced than the capacitance of each individual capacitor. On the other hand, when at least one of capacitances of two or more capacitors connected in series has a negative value, the total capacitance may have a positive value and may be greater than an absolute value of each individual capacitance.

When the ferroelectric material layer having a negative capacitance and the paraelectric material layer having a positive capacitance are connected in series, the total capacitance value of the ferroelectric material layer and the paraelectric material layer, which are connected in series, may be increased. Based on the total capacitance value that is increased, a transistor having the ferroelectric material layer may have a subthreshold swing (SS) less than 60 mV/decade at a room temperature.

The ferroelectric material layer may have ferroelectric characteristics. The ferroelectric material layer may include at least one of, for example, hafnium oxide, hafnium zirconium oxide, barium strontium titanium oxide, barium titanium oxide, or lead zirconium titanium oxide. In this case, for example, the hafnium zirconium oxide may be a material doped with zirconium (Zr) in hafnium oxide. For another example, the hafnium zirconium oxide may be a compound of hafnium (Hf), zirconium (Zr) and oxygen (O).

The ferroelectric material layer may further include a dopant; that is, the ferroelectric material may be doped, at a prescribed concentration level, with an impurity or dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), or tin (Sn). A type of the dopant included in the ferroelectric material layer may be varied depending on the ferroelectric material of the ferroelectric material layer.

When the ferroelectric material layer includes hafnium oxide, the dopant included in the ferroelectric material layer may include at least one of gadolinium (Gd), silicon (Si), zirconium (Zr), aluminum (Al), or yttrium (Y).

When the dopant is aluminum (Al), the ferroelectric material layer may include aluminum of 3 atomic percent (at %) to 8 at %. In this case, a ratio of the dopant may be a ratio of aluminum to a sum of hafnium and aluminum.

When the dopant is silicon (Si), the ferroelectric material layer may include silicon of 2 at % to 10 at %. When the dopant is yttrium (Y), the ferroelectric material layer may include yttrium of 2 at % to 10 at %. When the dopant is gadolinium (Gd), the ferroelectric material layer may include gadolinium of 1 at % to 7 at %. When the dopant is zirconium (Zr), the ferroelectric material layer may include zirconium of 50 at % to 80 at %.

The paraelectric material layer may have paraelectric characteristics. The paraelectric material layer may include at least one of, for example, silicon oxide or metal oxide having a high dielectric constant. The metal oxide included in the paraelectric material layer may include at least one of, for example, hafnium oxide, zirconium oxide, or aluminum oxide, but is not limited thereto.

The ferroelectric material layer and the paraelectric material layer may include the same material. Although the ferroelectric material layer has ferroelectric characteristics, the paraelectric material layer may not have ferroelectric characteristics. For example, when the ferroelectric material layer and the paraelectric material layer include hafnium oxide, a crystal structure of hafnium oxide included in the ferroelectric material layer may be different from that of hafnium oxide included in the paraelectric material layer.

The ferroelectric material layer may have a cross-sectional thickness having ferroelectric characteristics. The thickness of the ferroelectric material layer may be, for example, 0.5 nm to 10 nm, but is not limited thereto. Since a threshold thickness indicating ferroelectric characteristics may be varied depending on each ferroelectric material, the thickness of the ferroelectric material layer may be varied depending on the ferroelectric material.

For example, the gate dielectric layer 120 may include one ferroelectric material layer. For another example, the gate dielectric layer 120 may include a plurality of ferroelectric material layers spaced apart from each other. The gate dielectric layer 120 may have a stacked layer structure in which a plurality of ferroelectric material layers and a plurality of paraelectric material layers are alternately stacked.

The interlayer insulating layers 110 and 210 may cover the electronic element TR. The term “cover” (or “covers” or “covering,” or like terms) as may be used herein is intended to broadly refer to a material, layer or structure being on or over another material, layer or structure, but does not require the material, layer or structure to entirely cover the other material, layer or structure. For example, the interlayer insulating layers 110 and 210 may include a first interlayer insulating layer 110 and a second interlayer insulating layer 210, which are sequentially stacked, in the third direction Z, on the frontside of the substrate 100 (e.g., the upper surface of the substrate 100). The first interlayer insulating layer 110 may cover the field insulating layer 105 and the source/drain regions 160. The second interlayer insulating layer 210 may cover the gate structure G and the first interlayer insulating layer 110.

The interlayer insulating layers 110 and 210 may include at least one of, for example, silicon oxide, silicon oxynitride and a low-k material having a dielectric constant lower than that of silicon oxide, but is not limited thereto.

The frontside interconnection structures 311 to 314, FM1, FM2, FV1 and FV2 may be disposed on the frontside of the substrate 100 (e.g., the upper surface of the substrate 100). For example, the frontside interconnection structures 311 to 314, FM1, FM2, FV1 and FV2 may be formed on the upper surface of the second interlayer insulating layer 210. The frontside interconnection structures 311 to 314, FM1, FM2, FV1 and FV2 may provide a signal line and a power line for various electronic elements (e.g., the electronic element TR) formed on the frontside of the substrate 100. The frontside interconnection structures 311 to 314, FM1, FM2, FV1 and FV2 may include a plurality of frontside interconnection insulating layers 311 to 314, a plurality of frontside line patterns FM1 and FM2 and a plurality of frontside via patterns FV1 and FV2. The number, number of layers and arrangement of the frontside interconnection insulating layers 311 to 314, the frontside line patterns FM1 and FM2 and the frontside via patterns FV1 and FV2 are only exemplary, and are not limited to the shown example.

The frontside interconnection insulating layers 311 to 314 may be sequentially stacked on the frontside of the substrate 100 (e.g., an upper surface of the second interlayer insulating layer 210) in the third direction Z. The frontside line patterns FM1 and FM2 and the frontside via patterns FV1 and FV2 may be formed in the frontside interconnection insulating layers 311 to 314. The frontside line patterns FM1 and FM2 and the frontside via patterns FV1 and FV2 may be insulated from each other by the frontside interconnection insulating layers 311 to 314.

The frontside line patterns FM1 and FM2 may be sequentially stacked, in the third direction Z, on the frontside of the substrate 100. For example, the first frontside line pattern FM1 may be formed in the second frontside interconnection insulating layer 312, and the second frontside line pattern FM2 may be formed in the fourth frontside interconnection insulating layer 314.

The frontside via patterns FV1 and FV2 may be sequentially stacked, in the third direction Z, on the frontside of the substrate 100. The frontside via patterns FV1 and FV2 may interconnect the frontside line patterns FM1 and FM2. For example, the first frontside via pattern FV1 may be connected to the first frontside line pattern FM1 by passing through the first frontside interconnection insulating layer 311, and the second frontside via pattern FV2 may connect the first frontside line pattern FM1 with the second frontside line pattern FM2 by passing through the third frontside interconnection insulating layer 313. The term “connected,” as may be used herein, is broadly intended to include an electrical and/or physical connection, and may include other intervening elements.

In some embodiments, a width of each of the frontside via patterns FV1 and FV2 may be reduced as it becomes close to the frontside of the substrate 100; that is, sidewalls of each of the frontside via patterns FV1, FV2 may be inwardly sloped (i.e., inclined) such that an upper surface of the frontside via patterns FV1, FV2 may be wider (in the second direction Y) than a lower surface of the frontside via patterns FV1, FV2 as the frontside via patterns FV1, FV2 extend in the third direction Z toward the substrate 100. This may be due, at least in part, to characteristics of an etching process for forming frontside via patterns FV1 and FV2.

The frontside interconnection structures 311 to 314, FM1, FM2, FV1 and FV2 may be connected to the electronic element TR. For example, source/drain contacts CA and a gate contact CB may be formed on the substrate 100. The source/drain contacts CA may be connected to the source/drain regions 160 by passing through the interlayer insulating layers 110 and 210. The gate contact CB may be connected to the gate electrode 130 by passing through the gate capping pattern 150, the interlayer insulating layers 110 and 210 and the first interconnection insulating layer 311.

In some embodiments, the source/drain contact CA may connect the source/drain regions 160 with the first frontside via pattern FV1. Unlike the shown example, in some other embodiments, the source/drain contacts CA may connect the source/drain regions 160 with the first frontside line pattern FM1 by passing through the interlayer insulating layers 110 and 210 and the first frontside interconnection insulating layer 311.

In some embodiments, the gate contact CB may connect the gate electrode 130 with the first frontside line pattern FM1. Unlike the shown example, in some other embodiments, the gate contact CB may connect the gate electrode 130 with the first frontside via pattern FV1 by passing through the interlayer insulating layers 110 and 210.

In some embodiments, a width of each of the source/drain contacts CA and the gate contact CB may be reduced as it becomes close to the frontside of the substrate 100; that is, sidewalls of each of the source/drain contacts CA and the gate contact CB may be inwardly sloped (i.e., inclined) such that an upper surface of the source/drain contacts CA and the gate contact CB may be wider (in the second direction Y) than a lower surface of the source/drain contacts CA and the gate contact CB as the source/drain contacts CA and the gate contact CB extend in the third direction Z toward the substrate 100. This may be due, at least in part, to characteristics of an etching process for forming the source/drain contacts CA and the gate contact CB.

The power lines PW1 and PW2 may be disposed on the substrate 100. The first and second power lines PW1 and PW2 may provide different power voltages to the electronic element TR. For example, the first power line PW1 may provide a source voltage V_{SS} to the electronic element TR, and the second power line PW2 may provide a drain voltage V_{DD} to the electronic element TR.

In some embodiments, the first and second power lines PW1 and PW2 may extend in the first direction X, respectively. In some embodiments, the first and second power lines PW1 and PW2 may be alternately arranged along the second direction Y.

In some embodiments, each of the power lines PW1 and PW2 may be interposed between the active regions AR1 and AR2. For example, the first power line PW1 may be interposed between the first active region AR1 and the second active region AR2.

In some embodiments, the power lines PW1 and PW2 may be formed on the interlayer insulating layers 110 and 210. In some embodiments, the power lines PW1 and PW2 may be disposed at the same level as a portion of the frontside line patterns FM1 and FM2. In this case, “disposed at the same level” may mean “disposed at the same height based on the frontside of the substrate 100;” that is, an upper surface of the power lines PW1 and PW2 may be coplanar with an upper surface of the frontside line patterns FM1 and FM2 in the third direction Z. In the present disclosure, the term “same” includes not only completely identical but also a fine difference that may occur due to a process margin or the like. For example, the power lines PW1 and PW2 may be disposed at the same level as the first frontside line pattern FM1.

In some embodiments, the first power line PW1 and/or the second power line PW2 may be connected to the source/drain regions 160. For example, the first power line PW1 may be connected to the source/drain contacts CA through the frontside line patterns FM1 and FM2 and the frontside via patterns FV1 and FV2. As a result, the first power line PW1 may be electrically connected to the source/drain regions 160.

The backside interconnection structures 321 to 325, BM1 to BM3, BV1 and BV2 may be disposed on the backside of the substrate 100 (for example, the lower surface of the substrate 100). The backside interconnection structures 321 to 325, BM1 to BM3, BV1 and BV2 may provide a signal line and a power line for various electronic elements (e.g., the electronic element TR) formed on the frontside of the substrate 100 (e.g., the upper surface of the substrate 100). For example, the backside interconnection structures 321 to 325, BM1 to BM3, BV1 and BV2 may include a plurality of backside interconnection insulating layers 321 to 315, a plurality of backside line patterns BM1 to BM3, and a plurality of backside via patterns BV1 and BV2. The number, number of layers and/or arrangement of the backside interconnection insulating layers 321 to 315, the backside line patterns BM1 to BM3 and the backside via patterns BV1 and BV2 are only exemplary, and are not limited to the shown example.

The backside interconnection insulating layers 321 to 325 may be sequentially stacked on the backside of the substrate 100 in the third direction Z. The backside interconnection patterns BM1 to BM3 and the backside via patterns BV1 and BV2 may be formed in the backside interconnection insulating layers 321 to 325. The backside line patterns BM1 to BM3 and the backside via patterns BV1 and BV2 may be insulated from each other by the backside interconnection insulating layers 321 to 325.

The backside line patterns BM1 to BM3 may be sequentially stacked in the third direction Z on the backside of the substrate 100. For example, the first backside line pattern BM1 may be formed in the first backside interconnection insulating layer 321, the second backside line pattern BM2 may be formed in the third backside interconnection insulating layer 323, and the third backside line pattern BM3 may be formed in the fifth backside interconnection insulating layer 325.

The backside via patterns BV1 and BV2 may be sequentially stacked in the third direction Z on the backside of the substrate 100. The backside via patterns BV1 and BV2 may interconnect the backside line patterns BM1 to BM3. For example, the first backside via pattern BV1 may connect the first backside line pattern BM1 with the second backside line pattern BM2 by passing through the second backside interconnection insulating layer 322, and the second backside via pattern BV2 may connect the second backside line pattern BM2 with the third backside line pattern BM3 by passing through the fourth backside interconnection insulating layer 324.

In some embodiments, a width of each of the backside via patterns BV1 and BV2 may be reduced as it becomes close to the backside of the substrate 100; that is, sidewalls of each of the backside via patterns BV1 and BV2 may be inwardly sloped (i.e., inclined) such that an upper surface of the backside via patterns BV1 and BV2 may be wider (in the second direction Y) than a lower surface of the backside via patterns BV1 and BV2 as the backside via patterns BV1 and BV2 extend in the third direction Z toward the substrate 100. This may be due at least in part to characteristics of an etching process for forming the backside via patterns BV1 and BV2.

Although not explicitly shown in detail, each of the frontside line patterns FM1 and FM2, the frontside via patterns FV1 and FV2, the backside line patterns BM1 to BM3 and the backside via patterns BV1 and BV2 may include a barrier conductive layer and a filling conductive layer. The barrier conductive layer may include a metal or a metal nitride to prevent diffusion of the filling conductive layer. The barrier conductive layer may include at least one of, for example, titanium (Ti), tantalum (Ta), tungsten (W), nickel (Ni), cobalt (Co), platinum (Pt), their alloy, or their nitride, but is not limited thereto. The filling conductive layer may include at least one of, for example, aluminum (Al), copper (Cu), tungsten (W), molybdenum (Mo), cobalt (Co), ruthenium (Ru) or their alloy, but is not limited thereto.

The backside interconnection structures 321 to 325, BM1 to BM3, BV1 and BV2 may be connected to the electronic element TR. For example, a through via TV may be formed on the substrate 100. The through via TV may connect the backside interconnection structures 321 to 325, BM1 to BM3, BV1 and BV2 with the frontside interconnection structures 311 to 314, FM1, FM2, FV1 and FV2 by passing through the substrate 100 and the interlayer insulating layers 110 and 210. In some embodiments, the through via TV may be interposed between the first and second active regions AR1 and AR2.

In some embodiments, the through via TV may connect the backside interconnection structures 321 to 325, BM1 to BM3, BV1 and BV2 with the first power line PW1 and/or the second power line PW2. For example, the through via TV may connect the backside interconnection structures 321 to 325, BM1 to BM3, BV1 and BV2 with the first power line PW1 by passing through the substrate 100, the interlayer insulating layers 110 and 210 and the first frontside interconnection insulating layer 311. As a result, the backside interconnection structures 321 to 325, BM1 to BM3, BV1 and BV2 may be electrically connected to the source/drain regions 160. The backside interconnection structures 321 to 325, BM1 to BM3, BV1 and BV2 may implement a power delivery network PDN on the backside of the substrate 100.

In some embodiments, a width of the through via TV may be reduced as the through via TV is directed from the backside interconnection structures 321 to 325, BM1 to BM3, BV1 and BV2 toward the frontside interconnection structures 311 to 314, FM1, FM2, FV1 and FV2; that is, sidewalls of the through via TV may be outwardly sloped (i.e., inclined) such that an upper surface of the through via TV may be narrower (in the second direction Y) than a lower surface of the through via TV as the through via TV extends in the third direction Z from the frontside interconnection structures 311 to 314, FM1, FM2, FV1 and FV2 toward the backside interconnection structures 321 to 325, BM1 to BM3, BV1 and BV2. This may be due at least in part to characteristics of an etching process for forming the through via TV.

In some embodiments, the through via TV may include a through conductive layer 192 and a through insulating layer 194. The through insulating layer 194 may extend along sides of the through conductive layer 192 in the third direction Z. The through insulating layer 194 may include an insulating material for electrically insulating the through conductive layer 192 from the substrate 100. The through insulating layer 194 may include at least one of, for example, silicon oxide (SiO₂), silicon oxynitride (SiON), silicon oxycarbonitride (SiOCN) or their combination, but is not limited thereto. The through conductive layer 192 may include at least one of, for example, aluminum (Al), copper (Cu), tungsten (W), molybdenum (Mo), cobalt (Co), ruthenium (Ru) or their alloy, but is not limited thereto.

As the semiconductor device is increasingly highly integrated, widths of the line patterns and the via patterns, which implement the semiconductor device, are gradually reduced. As a result, a voltage drop (for example, current-resistance (IR) drop) of the power delivery network PDN for supplying a power voltage to the electronic element has emerged as an important issue.

In the semiconductor device according to some embodiments, the power delivery network PDN may be implemented on the backside of the substrate 100 (e.g., the lower surface of the substrate 100) to have a reduced voltage drop. In detail, as described above, the backside interconnection structures 321 to 325, BM1 to BM3, BV1 and BV2 for implementing the power delivery network PDN may be disposed on the backside of the substrate 100. As a result, when compared with the power delivery network PDN implemented on the frontside of the substrate 100 (e.g., the upper surface of the substrate 100), the frontside interconnection structures 311 to 314, FM1, FM2, FV1 and FV2 may be formed to be relatively large. Accordingly, the semiconductor device according to some embodiments may provide an improved power performance area (PPA).

The dummy mold structure 410 may be disposed on the frontside interconnection structures 311 to 314, FM1, FM2, FV1 and FV2. Referring to FIG. 2, a cross-sectional thickness D2 of the dummy mold structure 410 in a vertical direction Z may be greater than a cross-sectional thickness D1 of the frontside interconnection structures 311 to 314, FM1, FM2, FV1 and FV2 in the vertical direction. In addition, the cross-sectional thickness D2 of the dummy mold structure 410 in the vertical direction Z may be equal to or greater than a sum of cross-sectional thicknesses of the electronic element TR and the frontside interconnection structure 311 to 314, FM1, FM2, FV1 and FV2 in the vertical direction. For example, the cross-sectional thickness D2 of the dummy mold structure 410 in the vertical direction Z may be 1 μm or more, but is not limited thereto.

For example, the dummy mold structure 410 may include silicon nitride (e.g., Si₃N₄). For another example, the dummy mold structure 410 may include silicon carbonitride. For other example, the dummy mold structure 410 may include silicon oxide. However, embodiments of the present disclosure are not limited to any specific material(s).

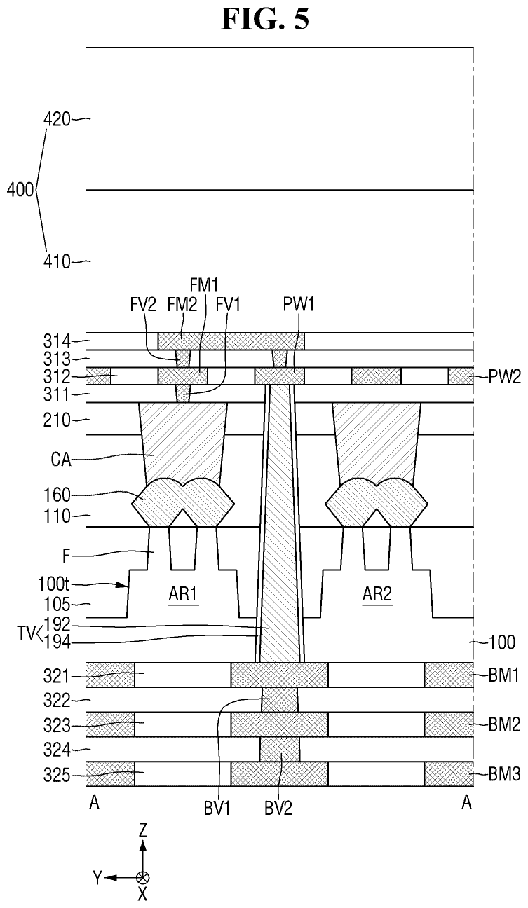

FIGS. 5 to 7 are views illustrating a semiconductor device according to some embodiments, and are cross-sectional views corresponding to FIG. 2. For convenience of description, portions duplicated with those described with reference to FIGS. 1 to 4 will be briefly described or omitted. For reference, FIGS. 5 to 7 are various cross-sectional views taken along line A-A of FIG. 1.

Referring to FIG. 5, the dummy mold structure 400 may include a first dummy mold layer 410 and a second dummy mold layer 420, which are sequentially stacked in the third direction Z on the frontside interconnection structures 311 to 314, FM1, FM2, FV1 and FV2.

In some embodiments, the first dummy mold layer 410 and the second dummy mold layer 420 may include their respective materials different from each other. In this case, for example, the first dummy mold layer 410 may include silicon nitride, and the second dummy mold layer 420 may include silicon oxide. For another example, the first dummy mold layer 410 may include silicon carbonitride, and the second dummy mold layer 420 may include silicon oxide. For another example, the first dummy mold layer may include silicon oxide 410, and the second dummy mold layer 420 may include silicon nitride. For another example, the first dummy mold layer may include silicon oxide 410, and the second dummy mold layer 420 may include silicon carbonitride.

The number of layers, material type and arrangement of the dummy mold structures 400 are only exemplary, and are not limited to the shown example.

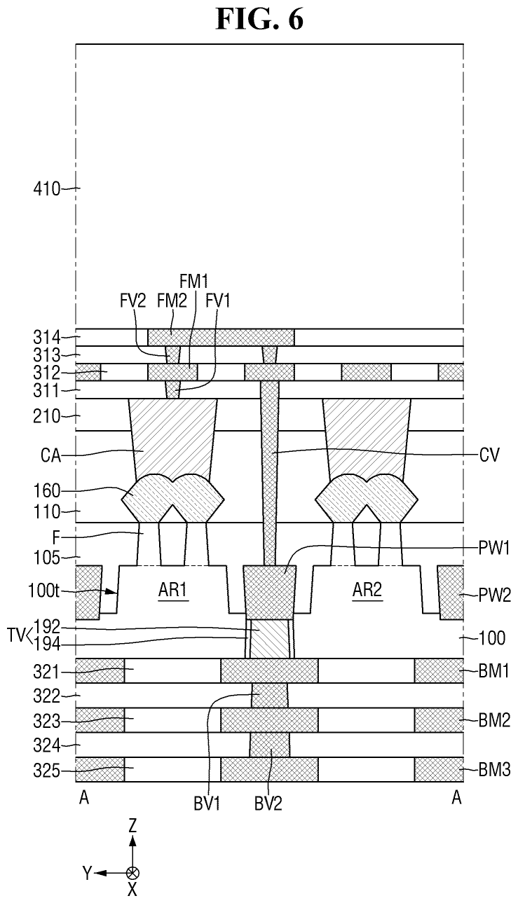

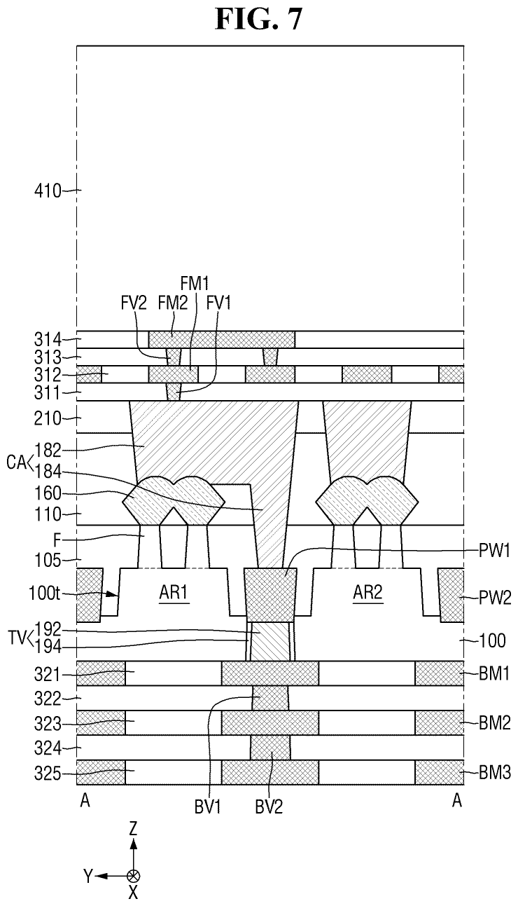

Referring to FIGS. 6 and 7, in the semiconductor device according to some embodiments, the power lines PW1 and/or PW2 may be embedded in the substrate 100.

For example, the first and second power lines PW1 and PW2 may be disposed in the element isolation trench 100t. The field insulating layer 105 may cover the power lines PW1 and PW2. In some embodiments, a portion of the field insulating layer 105 may be interposed between the substrate 100 and the power lines PW1 and PW2.

In FIG. 6, lower surfaces of the power lines PW1 and PW2 are shown to be lower than (i.e., extend below) a lower surface of the element isolation trench 100t, relative a lower surface of the substrate 100 (i.e., in the third direction Z), but this is only exemplary. As another example, the lower surfaces of the power lines PW1 and PW2 may be equal to or higher than the lower surface of the element isolation trench 100t.

In some embodiments, the through via TV may connect the first backside line pattern BM1 with the first power line PW1 and/or the second power line PW2 by extending in the third direction Z through at least a portion of the substrate 100.

Referring to FIG. 7, in the semiconductor device according to some embodiments, the source/drain contacts CA may include a first contact portion 182 and a second contact portion 184.

The first contact portion 182 may be in contact with the source/drain regions 160. The second contact portion 184 may extend from a lower surface of the first contact portion 182 toward the substrate 100, and thus may be in contact with the power lines PW1 and PW2. For example, the second contact portion 184 may be in contact with the first power line PW1 by extending at least partially through the field insulating layer 105 and the first interlayer insulating layer 110 in the third direction Z. The source/drain contacts CA are shown as including a first contact portion 182 and a second contact portion 184, but this is only exemplary. As another example, at least one of the source/drain contacts CA may not include the second contact portion 184.

Hereinafter, a method of fabricating a semiconductor device according to exemplary embodiments will be described below with reference to FIGS. 1 to 4 and 8 to 18.

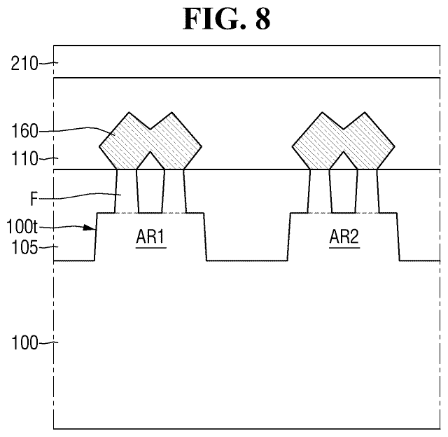

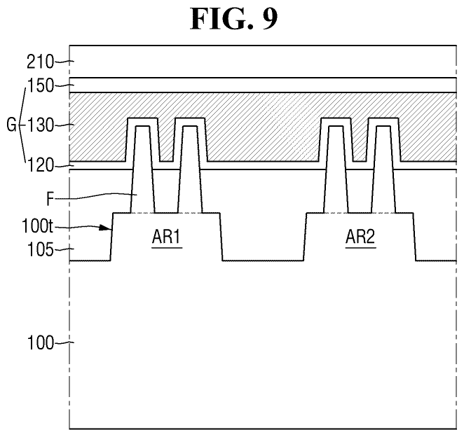

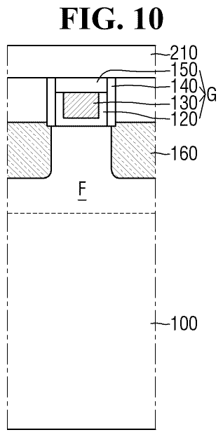

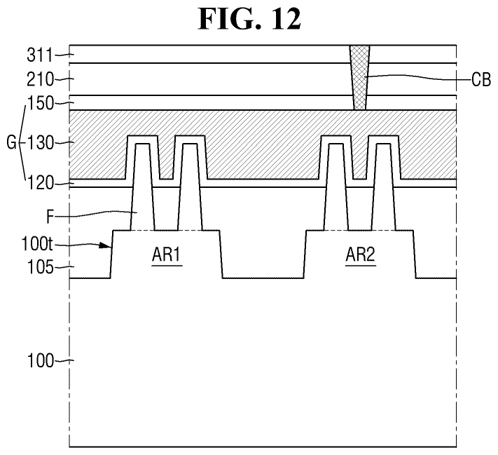

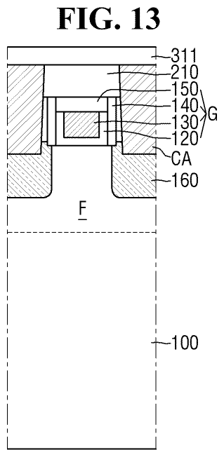

FIGS. 8 to 18 are cross-sectional views illustrating intermediate steps to describe an example method for fabricating a semiconductor device, according to some embodiments. For convenience of description, portions duplicated with those described with reference to FIGS. 1 to 4 will be briefly described or omitted. For reference, FIGS. 8, 11, 14 and 15 are cross-sectional views taken along the line A-A of FIG. 1. FIGS. 9 and 12 are cross-sectional views taken along line B-B of FIG. 1, respectively. FIGS. 10 and 13 are cross-sectional views taken along line C-C of FIG. 1, respectively.

Referring to FIGS. 8 to 10, electronic elements (e.g., the electronic element TR of FIG. 1) may be formed on a frontside of a substrate 100 (e.g., an upper surface of the substrate 100). In some embodiments, a field insulating layer 105 may be formed on the substrate 100.

For example, first and second active regions AR1 and AR2 may be formed. The first and second active regions AR1 and AR2 may be defined by an element isolation trench 100t in the substrate 100. The first and second active regions AR1 and AR2 may be separated from each other by the field insulating layer 105.

Subsequently, an active pattern F, a gate structure G and source/drain regions 160 may be formed on the first and second active regions AR1 and AR2.

Interlayer insulating layers 110 and 210 covering the electronic elements (e.g., the electronic element TR of FIG. 1) may be formed. The interlayer insulating layers 110 and 210 may cover the active pattern F, the gate structure G and the source/drain regions 160.

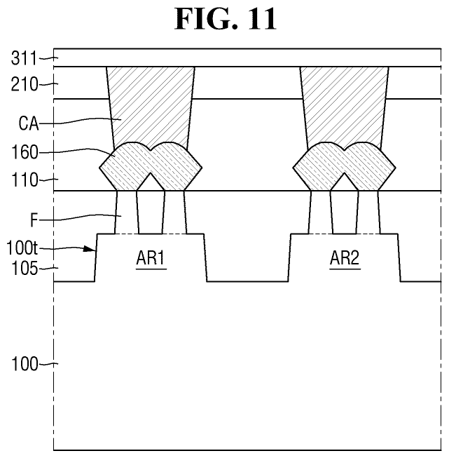

Referring to FIGS. 11 to 13, source/drain contacts CA and a gate contact CB are formed.

For example, the source/drain contacts CA may be connected to the source/drain regions 160 by passing through the interlayer insulating layer 210 and partially into the interlayer insulating layer 110.

Then, a first frontside interconnection insulating layer 311 covering the interlayer insulating layer 210 and the source/drain contacts CA may be formed. The gate contact CB may be connected to a gate electrode 130 by passing through the first frontside interconnection insulating layer 311, the interlayer insulating layer 210 and a gate capping pattern 150.

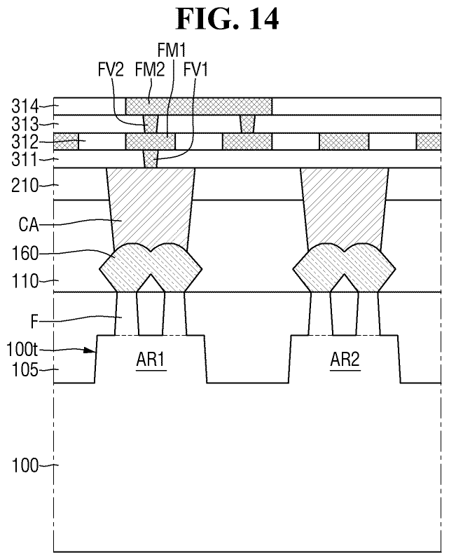

Referring to FIG. 14, frontside interconnection structures 311 to 314, FM1, FM2, FV1 and FV2 are formed on an upper surface of the interlayer insulating layer 210.

For example, first to fourth frontside interconnection insulating layers 311 to 314, first and second frontside line patterns FM1 and FM2 and first and second frontside via patterns FV1 and FV2 may be formed on the upper surface of the interlayer insulating layer 210. The frontside interconnection structures 311 to 314, FM1, FM2, FV1 and FV2 may provide a signal line and a power line for various electronic elements (e.g., the electronic element TR of FIG. 1) formed on the frontside of the substrate 100.

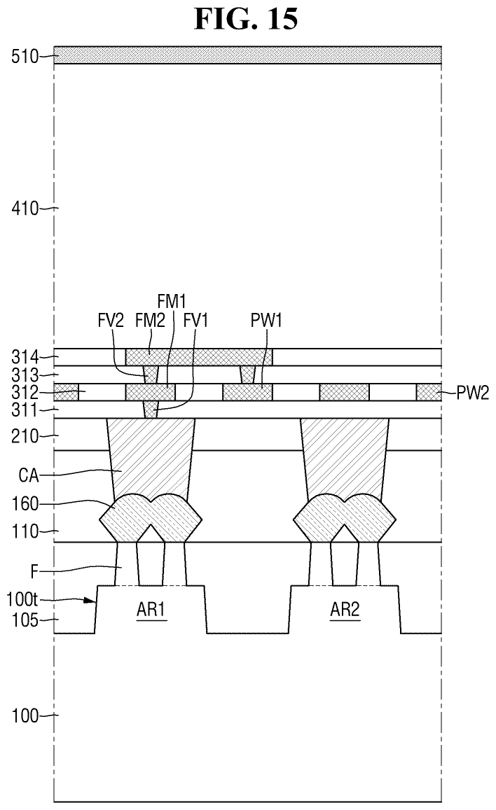

In some embodiments, power lines PW1 and PW2 disposed at the same level as a portion of the frontside line patterns FM1 and FM2 may be formed. For example, the power lines PW1 and PW2 may be disposed at the same level as the first frontside line pattern FM1 (see FIG. 15).

Referring to FIG. 15, a first dummy mold structure 410 in which a first bonding layer 510 is formed may be formed on the frontside interconnection structures 311 to 314, FM1, FM2, FV1 and FV2. The first dummy mold structure 410 may be formed between the frontside interconnection structures 311 to 314, FM1, FM2, FV1 and FV2 and the first bonding layer 510.

For example, the first bonding layer 510 may include, but is not limited to, silicon carbonitride.

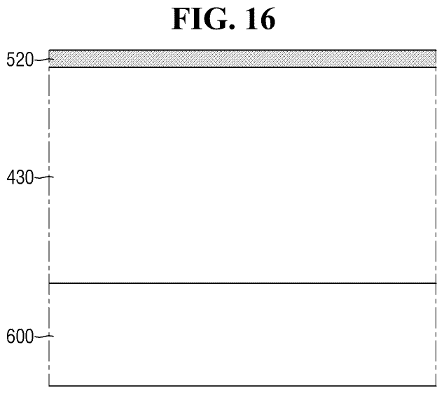

Referring to FIG. 16, a carrier substrate 600 including a first surface and a second surface, the second surface being opposite the first surface, may be provided. A second dummy mold structure 430 in which a second bonding layer 520 is formed may be formed on the first surface of the carrier substrate 600. The second dummy mold structure 430 may be formed between the carrier substrate 600 and the second bonding layer 520.

For example, the second bonding layer 520 may include, but is not limited to, silicon carbonitride.

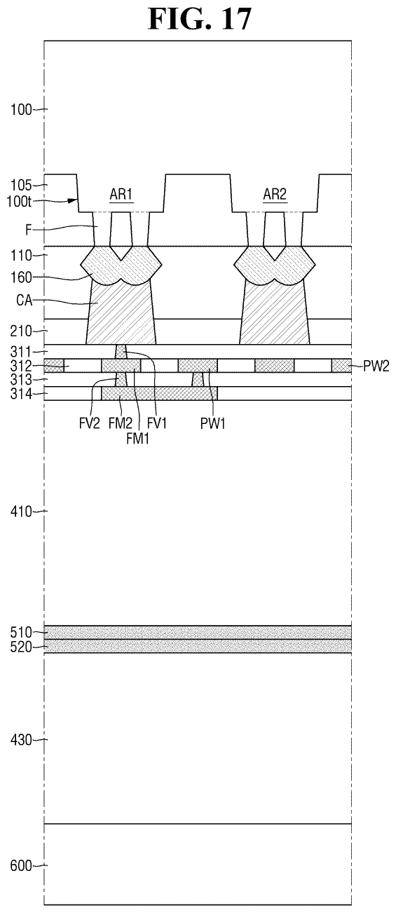

Referring to FIG. 17, the carrier substrate 600 is attached onto the frontside interconnection structures 311 to 314, FM1, FM2, FV1 and FV2. The first bonding layer 510 and the second bonding layer 520 may be disposed to face each other to bond (i.e., adjoin, attach, connect, adhere, or the like) the substrate 100 and the carrier substrate 600 to each other.

For example, the carrier substrate 600 may be attached onto the fourth frontside interconnection insulating layer 314. The carrier substrate 600 may function as a support substrate for supporting the semiconductor device attached thereto in subsequent processes. After the carrier substrate 600 is attached, the substrate 100 may be reversed (i.e., flipped upside down) such that its backside is directed upward.

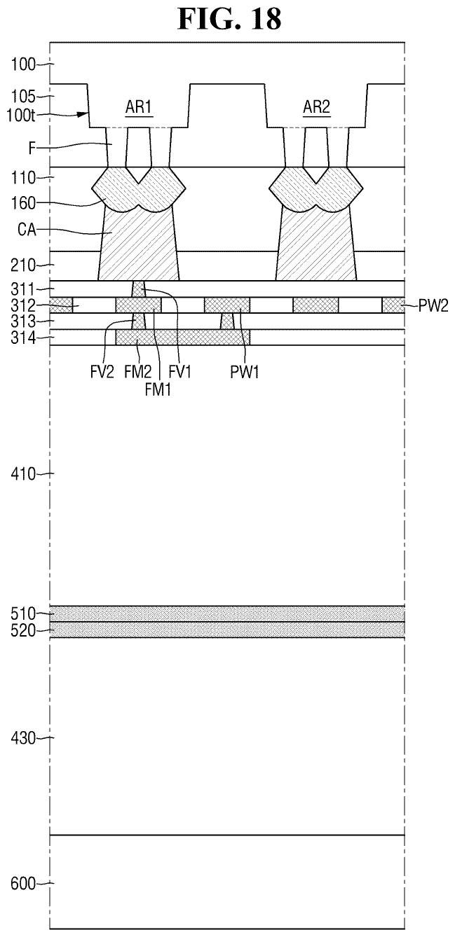

Referring to FIG. 18, a thinning process may be performed for the backside of the substrate 100.

For example, a back grinding or chemical mechanical polishing (CMP) process for the backside of the substrate 100 may be performed. As a result, a cross-sectional thickness of the substrate 100 may be reduced and then thinned.

In the conventional back grinding process, a distortion phenomenon may occur in the semiconductor device due to a difference in physical properties between various membranes formed in the semiconductor device.

In some embodiments, a dummy mold structure may be formed between the substrate 100 and the first bonding layer 510 and between the carrier substrate 600 and the second bonding layer 520, thereby alleviating the distortion phenomenon that may occur in the back grinding process or controlling distortion in a specific direction.

In some embodiments, the first dummy mold structure 410 and the second dummy mold structure 430 may include the same material. For example, the first and second dummy mold structures 410 and 430 may include silicon nitride (e.g., Si₃N₄). For another example, the first and second dummy mold structures 410 and 430 may include silicon carbonitride.

In some other embodiments, the first dummy mold structure 410 and the second dummy mold structure 430 may include their respective materials different from each other. For example, the first dummy mold structure 410 may include silicon oxide, and the second dummy mold structure 430 may include silicon nitride (e.g., Si₃N₄). For another example, the first dummy mold structure 410 may include silicon nitride (e.g., Si₃N₄), and the second dummy mold structure 430 may include silicon oxide.

Afterwards, a through via TV connected to the frontside interconnection structures 311 to 314, FM1, FM2, FV1 and FV2 may be formed (see, e.g., FIG. 2).

For example, the through via TV may be formed connected to the power line PW1 by passing through the substrate 100, the field insulating layer 105, the interlayer insulating layers 110 and 210 and the first frontside interconnection insulating layer 311. In some embodiments, the through via TV may include a through conductive layer 192 and a through insulating layer 194 (FIG. 2).

Afterwards, backside interconnection structures 321 to 325, BM1 to BM3, BV1 and BV2 are formed on the backside of the substrate 100 (see, e.g., FIG. 2).

The backside interconnection structures 321 to 325, BM1 to BM3, BV1 and BV2 formed may be connected to the through via TV. Accordingly, the backside interconnection structures 321 to 325, BM1 to BM3, BV1 and BV2 may provide a signal line and a power line for various electronic elements (e.g., the electronic element TR of FIG. 1) formed on the frontside of the substrate 100 (FIG. 2).

Then, the carrier substrate 600 may be removed. After the carrier substrate 600 is removed, the substrate 100 may be reversed such that its frontside is directed upward. Accordingly, the semiconductor device described with reference to FIGS. 1 to 4 may be fabricated. Although not explicitly shown in detail, at least a portion of the first bonding layer 510 may remain on the dummy mold structure 410 of the semiconductor device of FIGS. 2 to 4, but is not limited thereto.

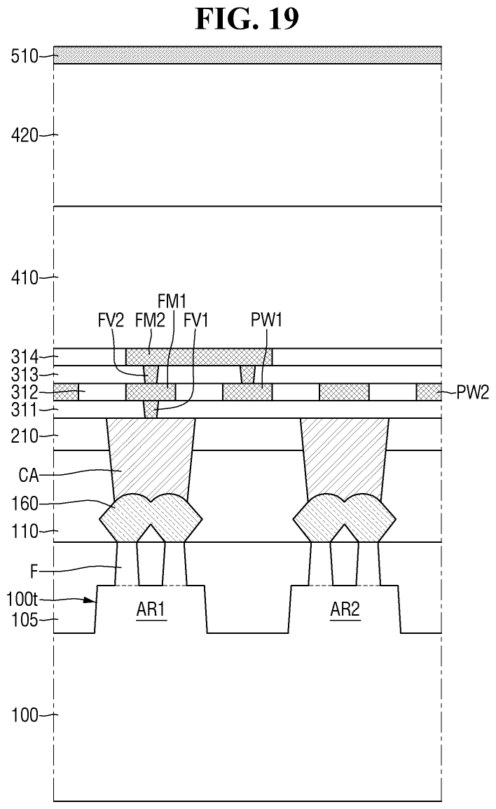

FIGS. 19 to 21 are cross-sectional views illustrating intermediate processing steps to describe an example method for fabricating a semiconductor device according to some embodiments. For convenience of description, portions duplicated with those described with reference to FIG. 5 will be briefly described or omitted. For reference, FIG. 19 is a cross-sectional view taken along line A-A of FIG. 1.

Referring to FIG. 19, a first dummy mold layer 410 and a second dummy mold layer 420, which are sequentially stacked in a vertical (Z) direction on the frontside interconnection structures 311 to 314, FM1, FM2, FV1 and FV2, may be formed. The first dummy mold layer 410 and the second dummy mold layer 420 may be formed between the frontside interconnection structures 311 to 314, FM1, FM2, FV1 and FV2 and the first bonding layer 510.

For example, the first bonding layer 510 may include, but is not limited to, silicon carbonitride.

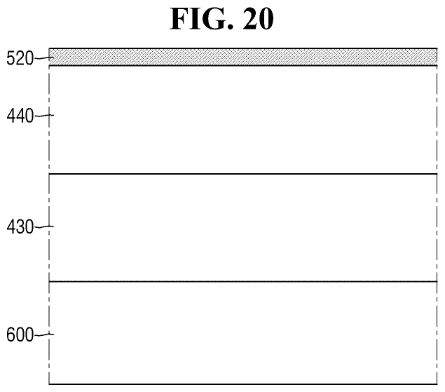

Referring to FIG. 20, a carrier substrate 600 including a first surface and a second surface, the second surface being opposite the first surface, may be provided. A third dummy mold layer 430 and a fourth dummy mold layer 440, which are sequentially stacked in the vertical direction, may be formed on one surface of the carrier substrate 600. The third dummy mold layer 430 and the fourth dummy mold layer 440 may be formed between the carrier substrate 600 and the second bonding layer 520.

For example, the second bonding layer 520 may include, but is not limited to, silicon carbonitride.

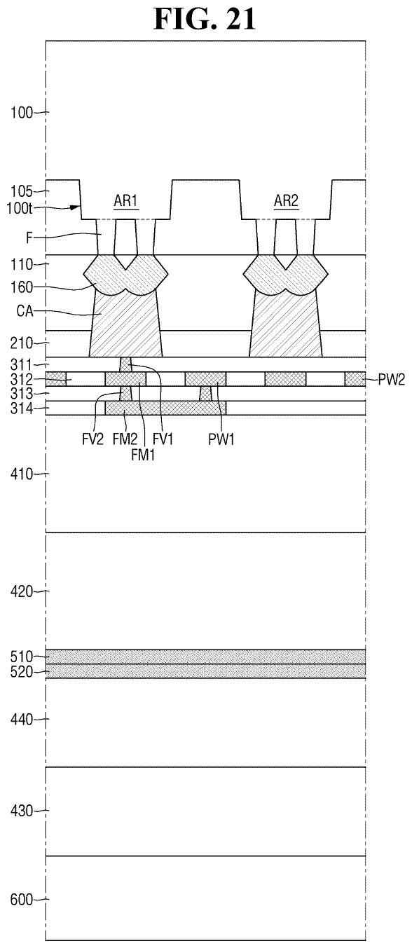

Referring to FIG. 21, a carrier substrate 600 is attached on the frontside interconnection structures 311 to 314, FM1, FM2, FV1 and FV2. The substrate 100 and the carrier substrate 600 may be bonded by disposing the first bonding layer 510 and the second bonding layer 520 to face each other.

For example, a carrier substrate 600 may be attached to the fourth front-side inter-wiring insulating layer 314. The carrier substrate 600 may function as a support substrate for supporting the semiconductor device attached thereto in subsequent processes. After the carrier substrate 600 is attached, the substrate 100 may be reversed such that its backside is directed upward.

Afterwards, a thinning process may be performed for the backside of the substrate 100. In accordance with this process, the semiconductor device described with reference to FIG. 5 may be fabricated.

The first dummy mold layer 410 and the second dummy mold layer 420 may include their respective materials different from each other, and the third dummy mold layer 430 and the fourth dummy mold layer 440 may include their respective materials different from each other.

In some embodiments, the first dummy mold layer 410 and the third dummy mold layer 430 may include the same material, and the second dummy mold layer 420 and the fourth dummy mold layer 440 may include the same material.

For example, each of the first dummy mold layer 410 and the third dummy mold layer 430 may include silicon nitride, and each of the second dummy mold layer 420 and the fourth dummy mold layer 440 may include silicon oxide.

For another example, each of the first dummy mold layer 410 and the third dummy mold layer 430 may include silicon carbonitride, and each of the second dummy mold layer 420 and the fourth dummy mold layer 440 may include silicon oxide.

In some other embodiments, the first dummy mold layer 410 and the fourth dummy mold layer 440 may include the same material, and the second dummy mold layer 420 and the third dummy mold layer 430 may include the same material.

For example, each of the first dummy mold layer 410 and the fourth dummy mold layer 440 may include silicon oxide, and each of the second dummy mold layer 420 and the third dummy mold layer 430 may include silicon nitride.

For another example, each of the first dummy mold layer 410 and the fourth dummy mold layer 440 may include silicon oxide, and each of the second dummy mold layer 420 and the third dummy mold layer 430 may include silicon carbonitride.

Although the embodiments of the present disclosure have been described with reference to the accompanying drawings, it will be apparent to those skilled in the art that the present disclosure can be fabricated in various forms without being limited to the above-described embodiments and can be embodied in other specific forms without departing from the technical spirits and essential characteristics. Thus, the above embodiments are to be considered in all respects as illustrative and not restrictive.

What is claimed is:

1. A semiconductor device, comprising:
a substrate including a frontside on which an active pattern is formed and a backside opposite the frontside;
an electronic element on an active region in which the active pattern is formed;
a frontside interconnection structure on the frontside of the substrate, the frontside interconnection structure comprising a power line electrically connected to the electronic element;
a backside interconnection structure on the backside of the substrate, the backside interconnection structure comprising a backside line electrically connected to the electronic element;
a through via extending vertically into the substrate and connecting the power line with the backside line; and
a dummy mold structure on the frontside interconnection structure, the dummy mold structure having a first cross-sectional thickness greater than a second cross-sectional thickness of the frontside interconnection structure.

2. The semiconductor device of claim 1, wherein the dummy mold structure includes silicon nitride.

3. The semiconductor device of claim 1, wherein the dummy mold structure includes silicon carbonitride.

4. The semiconductor device of claim 1, wherein the dummy mold structure includes a first dummy mold layer and a second dummy mold layer which are sequentially stacked on the frontside interconnection structure in a vertical direction, and
the first dummy mold layer and the second dummy mold layer comprise different materials.

5. The semiconductor device of claim 4, wherein the first dummy mold layer includes silicon nitride, and the second dummy mold layer includes silicon oxide.

6. The semiconductor device of claim 4, wherein the first dummy mold layer includes silicon oxide, and the second dummy mold layer includes silicon nitride.

7. The semiconductor device of claim 1, wherein a cross-sectional thickness of the dummy mold structure in a vertical direction is greater than or equal to 1 μm.

8. A method for fabricating a semiconductor device, the method comprising:
providing a semiconductor substrate including a first surface on which an active region is formed and a second surface opposite the first surface;
forming an electronic element on the active region;
forming a frontside interconnection structure on the first surface of the semiconductor substrate, the frontside interconnection structure being electrically connected to source/drain regions of the electronic element;
forming a first dummy mold structure on the frontside interconnection structure, the first dummy mold structure comprising a first bonding layer;
providing a carrier substrate including a third surface and a fourth surface, the fourth surface being opposite the third surface;
forming a second dummy mold structure on the third surface of the carrier substrate, the second dummy mold structure comprising a second bonding layer;
attaching the semiconductor substrate to the carrier substrate by disposing the first bonding layer and the second bonding layer to face each other; and
forming a backside interconnection structure on the second surface of the semiconductor substrate, the backside interconnection structure being electrically connected to the source/drain regions.

9. The method of claim 8, further comprising thinning the second surface of the semiconductor substrate, to reduce a cross-sectional thickness thereof, after forming the front side interconnection structure and before forming the backside interconnection structure.

10. The method of claim 8, wherein the first bonding layer includes the same material as that of the first dummy mold structure, and
the second bonding layer includes the same material as that of the second dummy mold structure.

11. The method of claim 8, wherein the first dummy mold structure and the second dummy mold structure include the same material.

12. The method of claim 8, wherein the first dummy mold structure and the second dummy mold structure include different materials.

13. The method of claim 8, wherein the first dummy mold structure includes a first dummy mold layer and a second dummy mold layer, which are sequentially stacked in a vertical direction between the frontside interconnection structure and the first bonding layer,
the second dummy mold structure includes a third dummy mold layer and a fourth dummy mold layer, which are sequentially stacked in the vertical direction between the third surface of the carrier substrate and the second bonding layer,
the first dummy mold layer and the second dummy mold layer include different materials, and
the third dummy mold layer and the fourth dummy mold layer include different materials.

14. The method of claim 13, wherein the first dummy mold layer and the fourth dummy mold layer include the same material, and
the second dummy mold layer and the third dummy mold layer include the same material.

15. The method of claim 13, wherein the first dummy mold layer and the third dummy mold layer include the same material, and
the second dummy mold layer and the fourth dummy mold layer include the same material.

16. A method for fabricating a semiconductor device, the method comprising:
providing a semiconductor substrate including an active region defined by an element isolation trench and including a first surface and a second surface, the second surface being opposite the first surface;
forming an electronic element including an active pattern on the active region and extending in a first direction parallel to an upper surface of the semiconductor substrate, a gate structure extending in a second direction intersecting the first direction and parallel to the upper surface of the semiconductor substrate, and source/drain regions on sides of the gate structure;
forming a frontside interconnection structure on the first surface of the semiconductor substrate, the frontside interconnection structure comprising a power line electrically connected to the source/drain regions;
forming a first dummy mold structure on the frontside interconnection structure, the first dummy mold structure comprising a first bonding layer;
providing a carrier substrate including a third surface and a fourth surface, the fourth surface being opposite the third surface; and
forming a second dummy mold structure on the third surface of the carrier substrate, the second dummy mold structure comprising a second bonding layer,
wherein the first dummy mold structure is between the frontside interconnection structure and the first bonding layer, and
the second dummy mold structure is between the third surface of the carrier substrate and the second bonding layer.

17. The method of claim 16, further comprising forming a backside interconnection structure on the second surface of the semiconductor substrate, the backside interconnection structure being connected to the source/drain regions.

18. The method of claim 16, wherein the first dummy mold structure and the second dummy mold structure include the same material.

19. The method of claim 16, wherein the first dummy mold structure and the second dummy mold structure include different materials.

20. The method of claim 16, wherein the first dummy mold structure includes a first dummy mold layer and a second dummy mold layer which are sequentially stacked, in a third direction perpendicular to the first and second directions, between the frontside interconnection structure and the first bonding layer, and
the second dummy mold structure includes a third dummy mold layer and a fourth dummy mold layer which are sequentially stacked in the third direction between the third surface of the carrier substrate and the second bonding layer.
